(19) United States
(12) Patent Application Publication
(10) Pub. No.: US 2023/0320037 A1
(43) Pub. Date: Oct. 5, 2023

(54) HEATSINK, METHOD FOR MANUFACTURING HEATSINK, AND ELECTRONIC COMPONENT PACKAGE USING SAID HEATSINK

(71) Applicant: KAGA, INC., Tokyo (JP)

(72) Inventors: Masaaki NOZAKI, Tokyo (JP); Yuji TANAKA, Ishikawa (JP); Shu MATSUURA, Ishikawa (JP); Yousuke NAKAMURA, Ishikawa (JP)

(73) Assignee: KAGA, INC., Tokyo (JP)

(21) Appl. No.: 18/024,832

(22) PCT Filed: Nov. 25, 2020
(86) PCT No.: PCT/JP2020/043772

§ 371 Date: Mar. 6, 2023

(30) Foreign Application Priority Data
Oct. 7, 2020 (JP) 2020-169917

(51) Int. Cl. H05K 7/20; H01L 23/367; H01L 21/48

(52) U.S. Cl. CPC H05K 7/20472; H01L 23/3675; H01L 21/4882

(57) ABSTRACT

To obtain a heatsink having a plurality of components firmly joined together. The heatsink includes a tabular base part having an electronic component contact surface on one side in the thickness direction thereof to make contact with an electronic component, a tabular column portion arranged in parallel on the other side of the base part across a heat dissipation space, and the column portions provided between the base part and the heat dissipating part. The heat dissipating part, the column portions, and the base part are provided with insertion holes that extend therethrough, and the heat dissipating part, the column portions, and the base part are fixed together by an inner member inserted into the insertion holes.

### TECHNICAL FIELD

The present invention relates to a heatsink designed to dissipate the heat from electronic components and the like, a method for manufacturing the heatsink, and an electronic component package that uses the heatsink.

### BACKGROUND ART

Inventions in this art made in the past include a heatsink provided with multiple protrusions that serve as heat dissipating parts on a substrate part, as shown for example in PTL 1.

For such a heatsink, an improvement of the heat dissipation performance is desired, which is achieved through an increase in surface area of the protrusions by increasing the size of the protrusions or by making the shape of the protrusions more complex.

Accordingly, it is proposed to make the heat dissipating part a separate component independent of the substrate part, and to join the heat dissipating part to the substrate part after processing it to have a relatively large shape or complex shape, so as to improve the processing ease or productivity.

### CITATION LIST

### Patent Literature

[PTL 1] Japanese Patent No. 6109274

### SUMMARY OF INVENTION

### Technical Problem

However, in the case where a separate heat dissipating part is joined to a substrate part as described above, the strength of this joint part or productivity sometimes becomes an issue.

### Solution to Problem

In view of this issue, the present invention includes the following configurations:

A heatsink including: a tabular base part including an electronic component contact surface on a first side in a thickness direction thereof to make contact with an electronic component; a tabular heat dissipating part arranged in parallel to the base part on a second side of the base part in the thickness direction across a heat dissipation space; and a column portion provided between the base part and the heat dissipating part, wherein: the heat dissipating part, the column portion, and the base part being provided with an insertion hole that extends therethrough; and the heat dissipating part, the column portion, and the base part are fixed together by an inner member inserted into the insertion hole.

### Advantageous Effects of Invention

The present invention with the above-described configuration can provide a heatsink having a plurality of components firmly joined together.

### BRIEF DESCRIPTION OF DRAWINGS

FIG. 1 is a perspective view illustrating an example of a heatsink according to the present invention.

FIG. 2 is an overall cross-sectional view illustrating a manufacturing process of the heatsink, (a) and (b) respectively showing the heatsink before and after formation of a recess.

FIG. 3 is an exploded perspective view illustrating the heatsink in a state before the formation of the recess.

FIG. 4 is an overall cross-sectional view illustrating a manufacturing process of another example of the heatsink according to the present invention, (a) and (b) respectively showing the heatsink before and after formation of a recess.

FIG. 5 is an exploded view of the heatsink in a state before the formation of the recess, in which main components are cut away to show longitudinal cross sections.

FIG. 6 is an overall cross-sectional view illustrating a manufacturing process of another example of the heatsink according to the present invention, (a) and (b) respectively showing the heatsink before and after formation of a recess.

FIG. 7 is an exploded view of the heatsink in a state before the formation of the recess, in which main components are cut away to show longitudinal cross sections.

FIG. 8 is an overall cross-sectional view illustrating a manufacturing process of another example of the heatsink according to the present invention, (a) and (b) respectively showing the heatsink before and after formation of a recess.

FIG. 9 is an exploded view of the heatsink in a state before the formation of the recess, in which main components are cut away to show longitudinal cross sections.

FIG. 10 is an overall cross-sectional view illustrating a manufacturing process of another example of the heatsink according to the present invention, (a) and (b) respectively showing the heatsink before and after formation of a recess.

FIG. 11 is an overall cross-sectional view illustrating a manufacturing process of another example of the heatsink according to the present invention, (a) and (b) respectively showing the heatsink before and after formation of a recess.

FIG. 12 is an overall cross-sectional view illustrating a manufacturing process of another example of the heatsink according to the present invention, (a) and (b) respectively showing the heatsink before and after formation of a small-diameter recess, and (c) and (d) respectively showing the heatsink before and after formation of a large-diameter recess.

FIG. 13 is an overall cross-sectional view illustrating a manufacturing process of another example of the heatsink according to the present invention, (a) and (b) respectively showing the heatsink before and after formation of a large-diameter recess, and (c) and (d) respectively showing the heatsink before and after formation of a small-diameter recess.

FIG. 14 is an overall cross-sectional view illustrating a manufacturing process of another example of the heatsink according to the present invention, (a) and (b) respectively showing the heatsink before and after an inner member is pressed by a first pressing punch, and (c) and (d) respectively showing the heatsink before and after the inner member is pressed by a second pressing punch.

FIG. 15 is an overall cross-sectional view illustrating a manufacturing process of another example of the heatsink according to the present invention, (a) and (b) respectively showing the heatsink before and after formation of a recess.

### DESCRIPTION OF EMBODIMENTS

The embodiments disclose the following features.

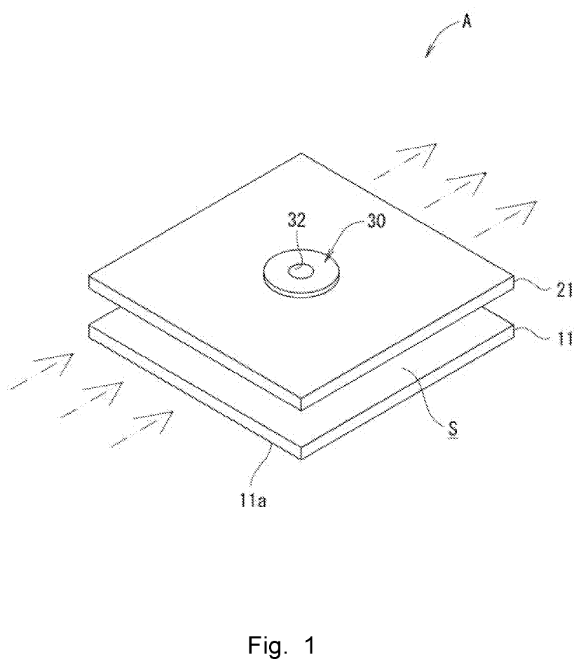

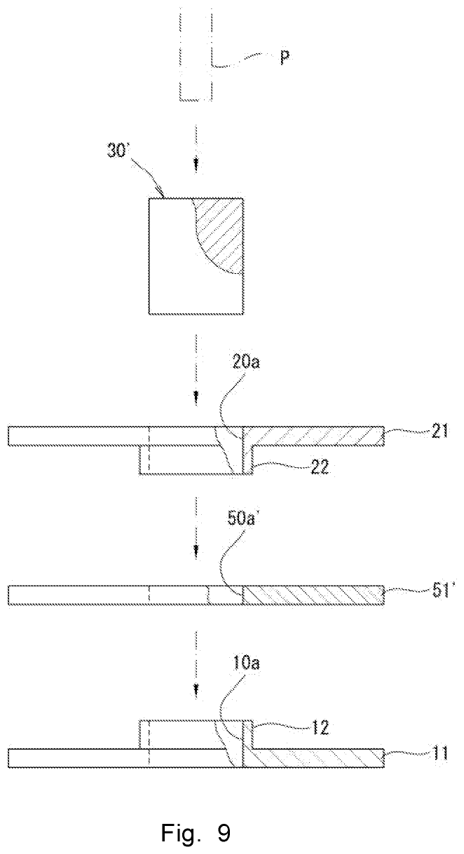

The first feature is a heatsink including: a tabular base part including an electronic component contact surface on one side in a thickness direction thereof to make contact with an electronic component; a tabular heat dissipating part arranged in parallel on the other side of the base part across a heat dissipation space; and a column portion provided between the base part and the heat dissipating part, wherein the heat dissipating part, the column portion, and the base part are provided with an insertion hole that extends therethrough; and the heat dissipating part, the column portion, and the base part are fixed together by an inner member inserted into the insertion hole (see FIG. 1 to FIG. 15).

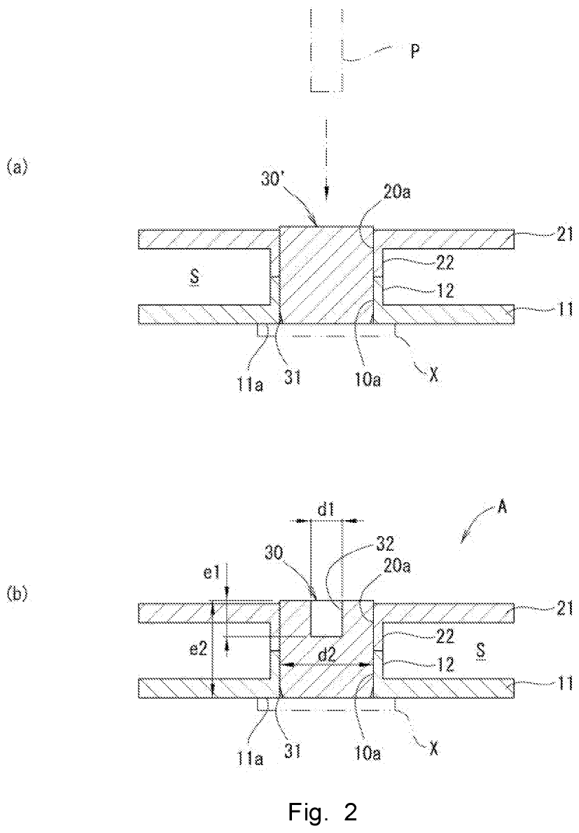

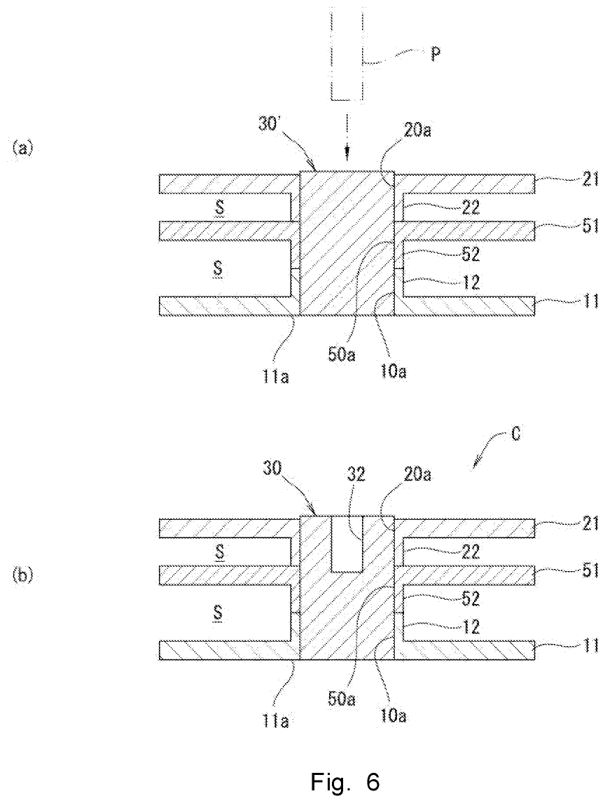

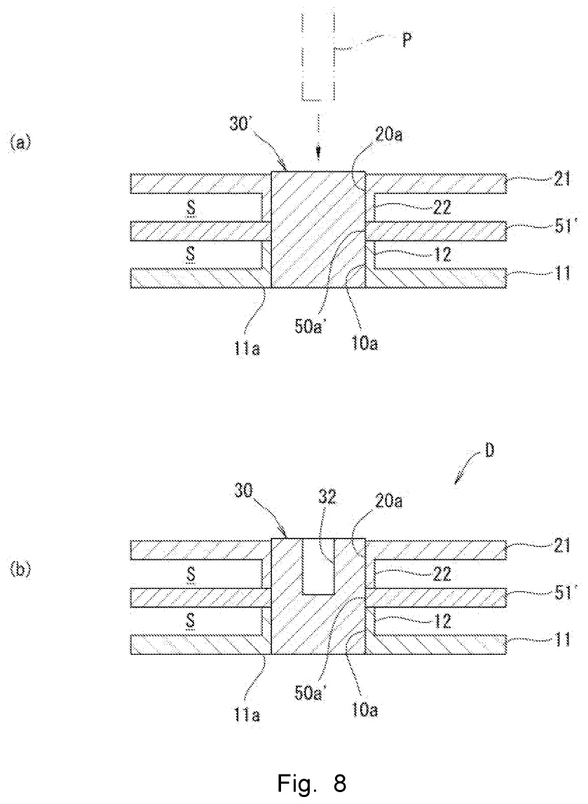

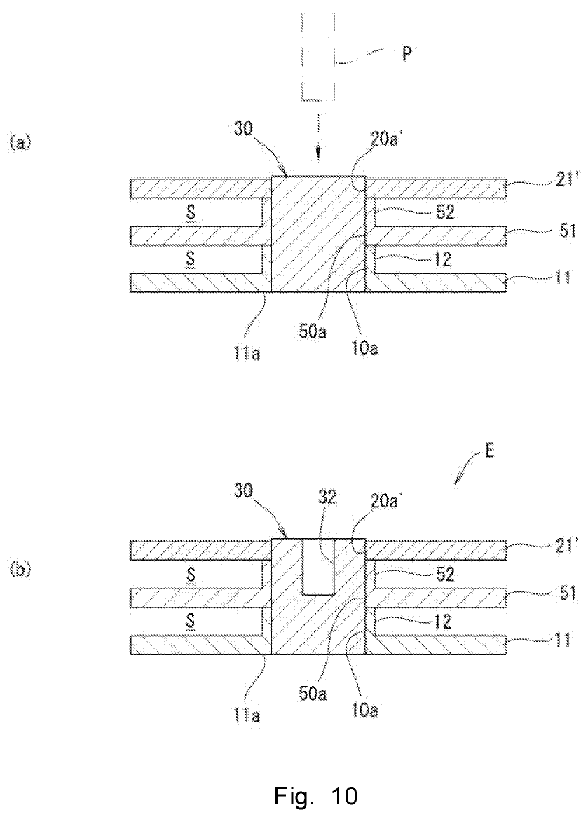

The second feature is that the inner member has an outer peripheral surface in pressure contact with an inner peripheral surface of the insertion hole (see FIG. 2, FIG. 6, FIG. 8, and FIG. 10 to FIG. 15).

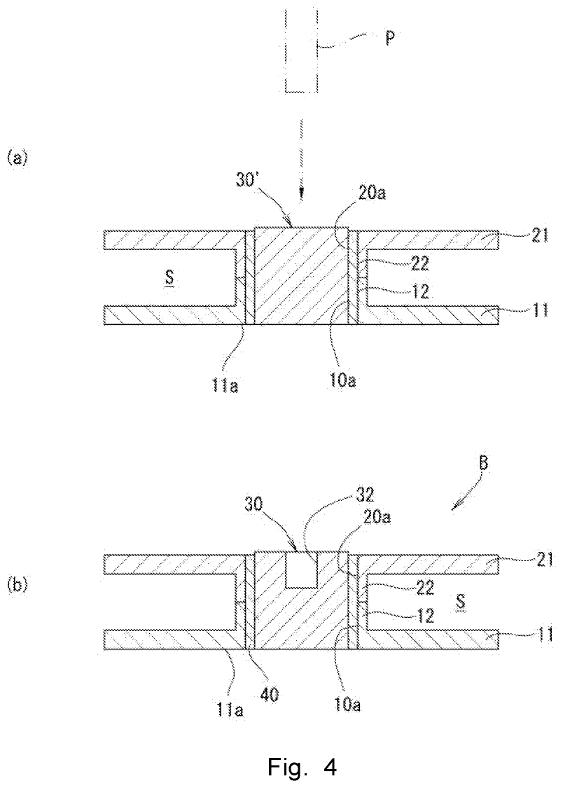

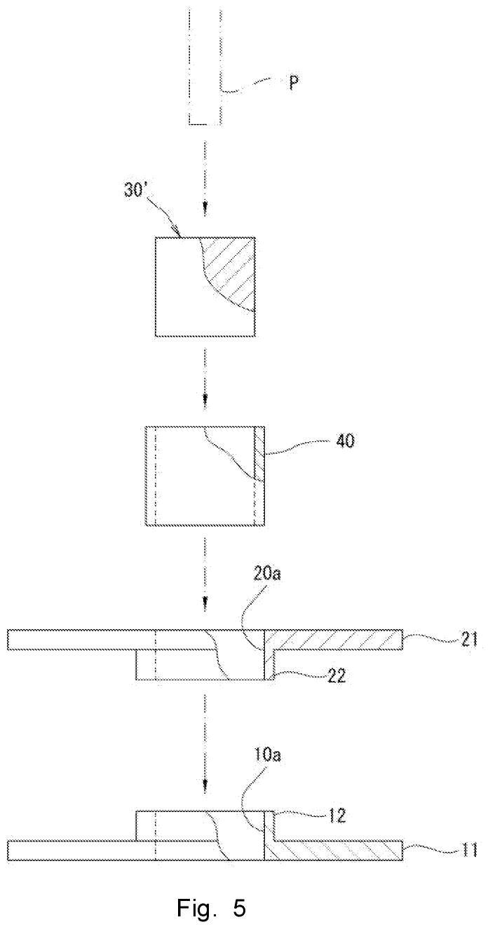

The third feature is that an inner cylindrical member is inserted in the insertion hole, the inner member has the outer peripheral surface in pressure contact with an inner peripheral surface of the inner cylindrical member, and the inner cylindrical member has an outer peripheral surface in pressure contact with an inner peripheral surface of the insertion hole (see FIG. 4 and FIG. 5).

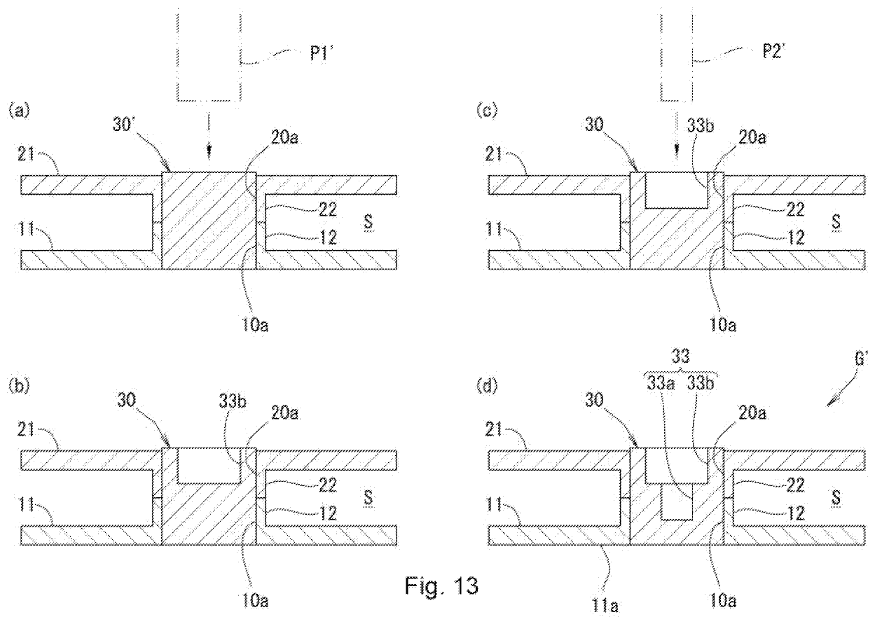

The fourth feature is that an outer cylindrical member is provided in an annular form to an outer circumferential part of the column portion, and the column portion has an outer peripheral surface in pressure contact with an inner peripheral surface of the outer cylindrical member (see FIG. 13).

The fifth feature is that a tabular intermediate heat dissipating part is provided between the heat dissipating part and the base part such that the column portion and a heat dissipation space are arranged on both sides in the thickness direction, the insertion hole extending through the heat dissipating part, the intermediate heat dissipating part, the column portion, and the base part. The heat dissipating part, the intermediate heat dissipating part, the column portion, and the base part are fixed together by the inner member inserted into the insertion hole (see FIG. 6 to FIG. 10).

The sixth feature is that the column portion is an integral part of the base part or the heat dissipating part (see FIG. 2 to FIG. 15).

The seventh feature is that a recess is provided in an end face of the inner member on the one side or on the other side (see FIG. 1 to FIG. 15).

The eighth feature is that the recess extends at least through the heat dissipating part or the base part into the column portion (see FIG. 2, FIG. 4, FIG. 6, FIG. 8, and FIG. 10 to FIG. 15).

The ninth feature is that the recess has an inner diameter set in a range of 20% to 80% of an outer diameter of the inner member.

The tenth feature is that the recess has a depth set in a range of 30% to 70% of a length of the inner member.

The eleventh feature is a manufacturing method of the above-described heatsink, including: an insertion step of inserting the inner member into the insertion hole; and a subsequent pressing step of forming the recess in the end face of the inner member by pressing the end face with a pressing punch having an outer diameter smaller than that of the inner member (see FIG. 2 to FIG. 15).

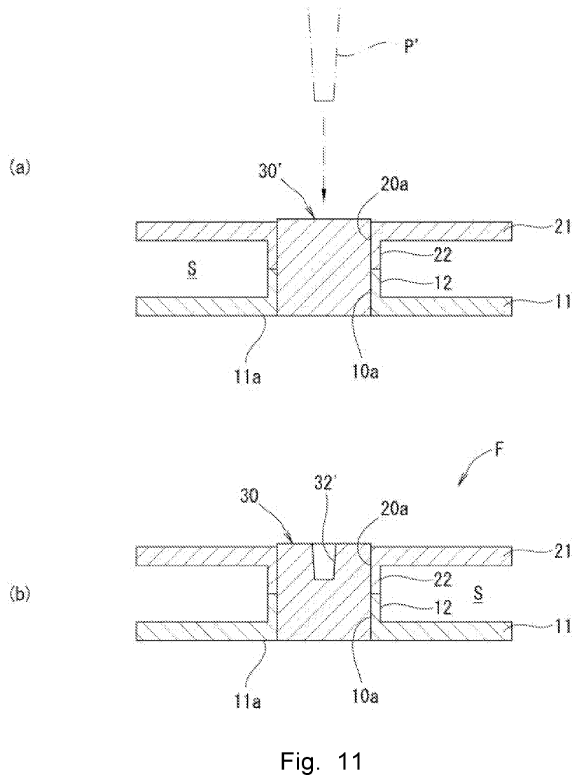

The twelfth feature is that the pressing punch, in a portion that forms the recess, has a smaller outer diameter at a distal end than the outer diameter therebehind (see FIG. 11).

The thirteenth feature is that the pressing punch has a portion that forms the recess, the portion gradually reducing in diameter toward a distal end thereof (see FIG. 11).

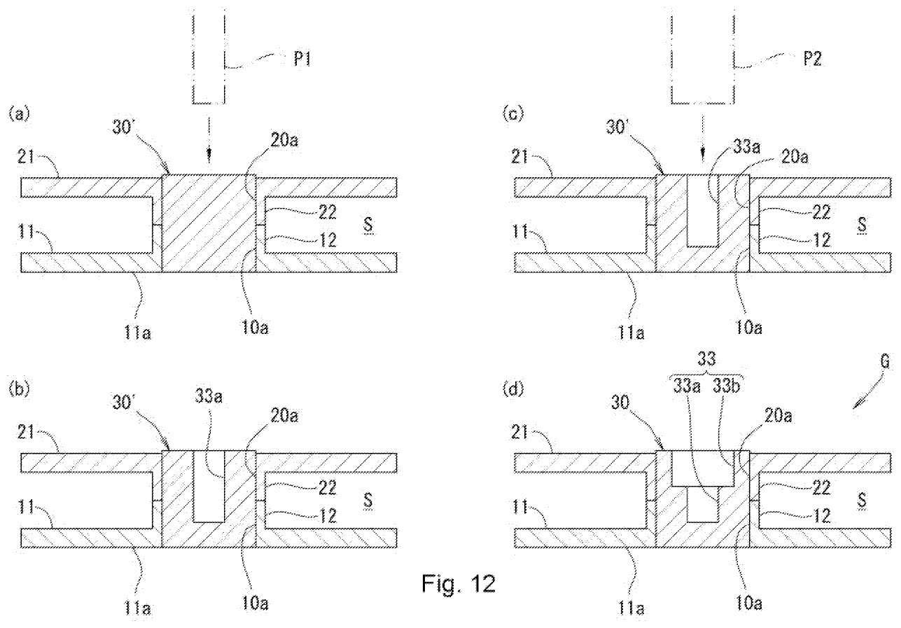

The fourteenth feature is that a first pressing punch and a second pressing punch having a larger outer diameter than that of the first pressing punch are used as the pressing punch, and in the pressing step, the first pressing punch is pressed against the end face of the inner member, after which the second pressing punch is pressed against the end face of the inner member, to form the recess (see FIG. 12).

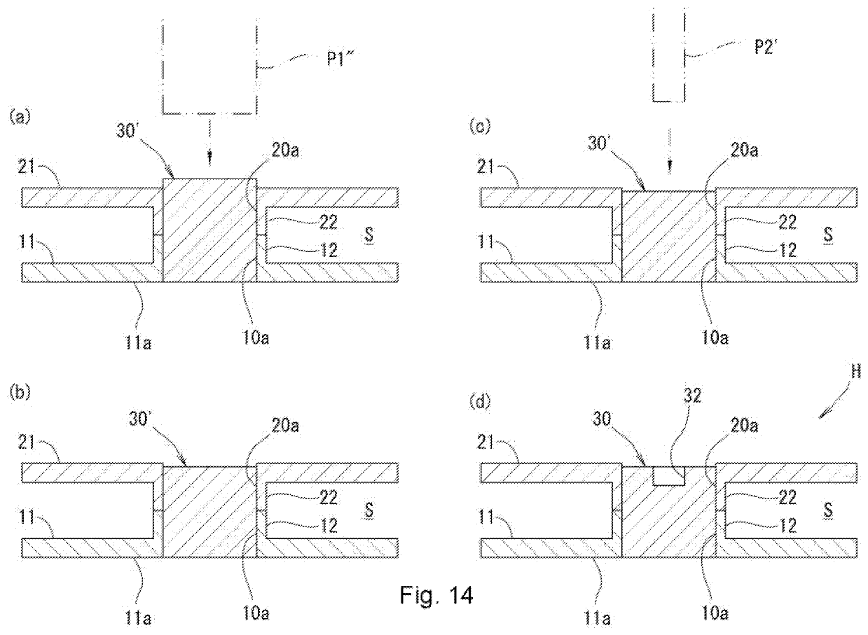

The fifteenth feature is that a first pressing punch and a second pressing punch having a smaller outer diameter than that of the first pressing punch are used as the pressing punch, and in the pressing step, the first pressing punch is pressed against the end face of the inner member, after which the second pressing punch is pressed against the end face inside an area that has been pressed, to form the recess (see FIG. 13 and FIG. 14).

The sixteenth feature is that the recess is formed in a shape of a stepped hole comprising a small-diameter recess and a large-diameter recess formed respectively by one and the other of the first pressing punch and the second pressing punch (see FIG. 12 and FIG. 13).

The seventeenth feature is that the first pressing punch has an outer diameter that is substantially equal to that of the inner member (see FIG. 14).

The eighteenth feature is an electronic component package including an electronic component in contact with the electronic component contact surface (see FIG. 2).

Next, specific embodiments having the above features are described in detail with reference to the drawings.

### <Heatsink A>

The heatsink A illustrated in FIGS. 1 to 3 includes a tabular base part 11 having an electronic component contact surface 11a on one side in the thickness direction thereof to make contact with an electronic component X (see FIG. 2), a tabular heat dissipating part 21 arranged in parallel on the other side of the base part 11 across a heat dissipation space S, and column portions 12 and 22 held between the base part 11 and the heat dissipating part 21.

The heat dissipating part 21, the column portions 22 and 12, and the base part 11 are provided with insertion holes 20a and 10a that extend therethrough, with an inner member 30 being inserted into these insertion holes 20a and 10a.

The heat dissipating part 21, the column portions 12 and 22, and the base part 11 are integrally fixed together by the inner member 30. A recess 32 is provided in an end face on one side (upper side in the illustrated example) of the inner member 30.

The base part 11 is made of a metal material having good heat conductivity (e.g., copper, aluminum, etc.) and formed in a rectangular flat plate shape. One side in the thickness direction (lower side in the drawing) of the base part is formed flat to make the electronic component contact surface 11a that is to be brought into contact with an electronic component X.

The other side (upper side) of the base part 11 is also formed flat in the illustrated example. In other examples than the illustrated one, surface irregularities or dissipation fins and the like may be provided on the upper side of the base part 11.

The column portion 12 protrudes upward in a center portion of this base part 11, with the insertion hole 10a extending through the base part 11 and the column portion 12.

The column portion 12 is an integral part of the base part 11 in the illustrated example; it is cylindrical and protrudes upward from the center portion of the base part 11. The insertion hole 10a extends through center portions of the base part 11 and the column portion 12 for the inner member 30 to be inserted.

The heat dissipating part 21, which is made of a metal material having good heat conductivity (e.g., copper, aluminum, etc.) similarly to the base part 11, has one side and the other side in the thickness direction and peripheral end faces serving as heat dissipating surfaces that are exposed to the outer air.

The column portion 22 is provided in a center portion of this heat dissipating part 21 such as to protrude toward the base part 11, with the insertion hole 20a extending through the heat dissipating part 21 and the column portion 22.

The one side and the other side in the thickness direction (upper side and lower side in the drawing) of the heat dissipating part 21 are both formed flat in the illustrated example. In other examples than the illustrated one, surface irregularities or dissipation fins and the like may be provided on one or both of the one side and the other side.

The column portion 22 is an integral part of the heat dissipating part 21 in the illustrated example; it is cylindrical and protrudes downward from the center portion of the other side of the heat dissipating part 21.

The insertion hole 20a extends through center portions of the heat dissipating part 21 and the column portion 22 for the inner member 30 to be inserted. This insertion hole 20a is formed with substantially the same inner diameter as that of the insertion hole 10a to be continuous with the insertion hole 10a of the base part 11.

The base part 11 and the heat dissipating part 21 in the illustrated example are components of the same material and of the same shape, one of these being used upside down. One of these components may be made of a material different from the other or have a different shape. Likewise, the column portion 12 and the column portion 22 may be of different materials or have different lengths.

While the column portions 12 and 22 are formed integrally with the base part 11 and the heat dissipating part 21 respectively in the illustrated example, one of the column portions 12 and 22 may be provided as a component separate from the base part 11 or the heat dissipating part 21.

The two column portions 12 and 22 are abutted against each other on their protruded ends to secure, between the base part 11 and the heat dissipating part 21, the heat dissipation space S in communication with the outer space (see FIG. 1 and FIG. 2).

The inner member 30 is made of a metal material having good heat conductivity and plasticity (e.g., copper, aluminum, etc.) and formed in a columnar shape. The inner member has the recess 32 in a center portion on one face at one axial end (upper end in the illustrated example).

This inner member 30 is inserted from the upper side downward into the heat dissipating part 21 and the base part 11 such as to extend therethrough before the formation of the recess 32.

Reference numeral 30′ in the drawing denotes the inner member before the recess 32 is formed.

The inner member 30 (or 30′) has one end in the direction in which it is inserted (extending direction) substantially flush with the electronic component contact surface 11a. The other end of the inner member 30 is substantially flush with or slightly protruded from the upper face of the heat dissipating part 21 (see FIG. 2).

The inner member 30 is provided with a chamfer 31 at the lower end on an outer peripheral surface to facilitate insertion into the insertion holes 20a and 10a. This chamfer 31 may be omitted.

The recess 32 in the illustrated example is located in a center portion of the inner member 30 and formed in a cylindrical shape with a bottom (put differently, in the shape of a circular blind hole) extending through the heat dissipating part 21 into the column portion 22. This recess 32 is formed by applying pressure with a pressing punch P by a manufacturing method to be described later.

This inner member 30′ before the recess 32 is formed is inserted into the insertion holes 10a and 20a such as to extend through the heat dissipating part 21, the column portions 22 and 12, and the base part 11.

The inner member 30 after the recess 32 has been formed plastically deforms radially outward so that its outer peripheral surface makes pressure contact with the inner peripheral surfaces of the insertion holes 10a and 20a.

In the illustrated example, the inner member 30′ before the recess 32 is formed has an outer diameter that is substantially the same as the inner diameters of the insertion holes 10a and 20a and that allows the inner member to be inserted into the insertion holes 10a and 20a.

The axial length of the inner member 30′ before the recess 32 is formed is set slightly longer than the entire length of the heat dissipating part 21, the column portions 22 and 12, and the base part 11 in the same direction.

Therefore, with the lower end face of the base part 11 being flush with the lower end face of the inner member 30′, the upper end face of the inner member 30′ slightly protrudes from the upper end face of the heat dissipating part 21 (see FIG. 2).

The inner diameter d1 of the recess 32 is preferably set in the range of 20% to 80% of the outer diameter d2 of the inner member 30.

With an inner diameter d1 below the above range, the radial expansion of the inner member 30 will be insufficient, as a result of which the joint strength between the inner member 30 and other components will be lowered significantly.

An inner diameter d1 exceeding the above range would lead to a warping deformation of the base part 11 or heat dissipating part 21 due to the plastic deformation on the outer peripheral side of the inner member 30. Namely, in the illustrated example, the base part 11 and the heat dissipating part 21 would become non-parallel, one or both of them skewed as a result of warping.

The depth e1 of the recess 32 is preferably set in the range of 30% to 70% of the axial length e2 of the inner member 30.

With a depth e1 below the above range, the radial expansion of the inner member 30 would be insufficient on its lower side.

With a depth e1 exceeding the above range, the pressing punch P pressed into the inner member would be harder to come out, which compromises the processing ease.

As described above, the outer diameter of the inner member 30′ substantially matches the insertion holes 10a and 20a in the illustrated example. In another example, the outer diameter of the inner member 30′ may be set slightly smaller than the diameters of the insertion holes 10a and 20a, in which case an outer peripheral surface of the inner member is brought into pressure contact with the inner peripheral surfaces of the insertion holes 10a and 20a when the inner member 30′ is inserted into the insertion holes 10a and 20a and plastically deformed radially outward by the formation of the recess 32 by the pressing punch P.

In another example, the outer diameter of the inner member 30′ may be set slightly larger than the diameters of the insertion holes 10a and 20a, and the inner member 30′ may be pressed into the insertion holes 10a and 20a. In this case the outer peripheral surface of the inner member will make even tighter contact with the inner peripheral surfaces of the insertion holes 10a and 20a when the inner member is plastically deformed radially outward by the formation of the recess 32 by the pressing punch P.

While the base part 11, the column portion 12, the heat dissipating part 21, the column portion 22, etc., should preferably be made of the same material, one or more of them may be made of a different material.

Next, a manufacturing method of the heatsink A with the above configuration is described in detail.

This manufacturing method includes an insertion step of inserting the inner member 30′ into the insertion holes 20a and 10a, and a subsequent pressing step of forming the recess 32 in an upper end face of the inner member 30′ by pressing the upper end face with the pressing punch P having an outer diameter smaller than that of the inner member 30′.

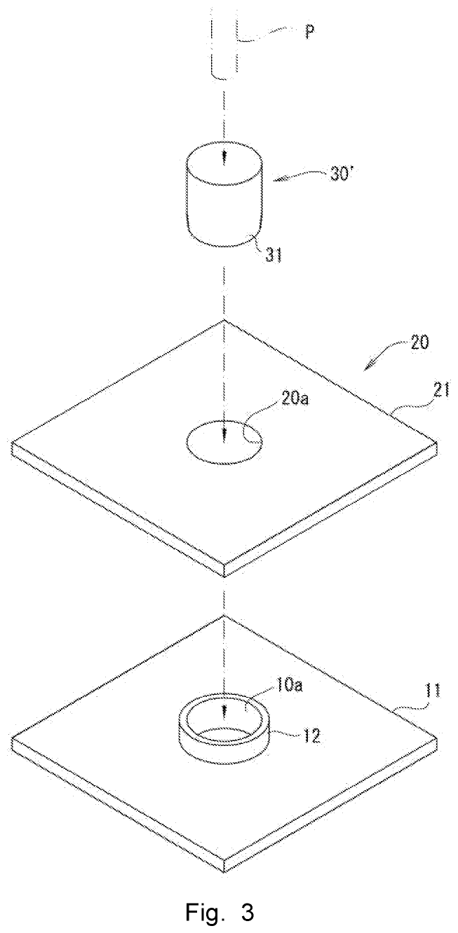

More specifically, first, the base part 11 is placed on a flat surface (not shown) such as a surface plate or the like with the column portion 12 upward, and the heat dissipating part 21 is placed on top of this base part 11 such that the column portion 22 is abutted against the column portion 12 from above (see FIG. 2 and FIG. 3).

The inner member 30′ is then inserted from above into the insertion holes 20a and 10a that are formed to extend through the heat dissipating part 21, the column portions 22 and 12, and the base part 11, until the lower end of this inner member 30′ abuts on the above-mentioned flat surface (such as surface plate). Thus the lower end of the inner member 30′ becomes flush with the lower end face of the base part 11 on the above-mentioned flat surface.

In this state, the pressing punch P is pressed against the upper end face of the inner member 30′ to form a recess 32 in the upper end face of the inner member 30 in a shape conforming to the outer face at the lower end of the pressing punch P.

The pressing causes the inner member 30′ to plastically deform radially outward. This brings an outer peripheral surface of the inner member 30 into pressure contact with the inner peripheral surfaces of the insertion holes 20a and 10a so that the base part 11, the column portions 12 and 22, and the heat dissipating part 21 are integrally fixed together.

During the pressing, the inner member 30′ also undergoes compressive deformation in the axial direction. However, the amount of this compressive deformation is smaller as compared to if the pressing punch P had substantially the same outer diameter as that of the inner member 30′.

Therefore, the inner member 30 comes to a state where its upper end face slightly protrudes from the upper end face of the heat dissipating part 21 (see FIG. 2).

In other examples than the illustrated one, the pressing punch P may be shifted downward with a larger stroke so that the upper end face of the inner member 30 is sunk down from the upper end face of the heat dissipating part 21.

According to the heatsink A with the above configuration and the manufacturing method thereof, the heat dissipating part 21 with the column portion 22, which is a separate component, can be joined firmly to the base part 11 and the column portion 12, ensuring good dimensional precision and qualities of the finished product. This in turn enables easy processing of the base part 11 and the heat dissipating part 21 in a complex shape such as surface irregularities or fins on the upper face and/or the lower face, or in a relatively large shape.

Namely, if the pressing punch P had the same outer diameter as that of the inner member 30, the base part 11 or heat dissipating part 21 could warp due to the plastic deformation near the outer periphery of the inner member 30 during the processing. In particular, a punching process in which the upper end face of the inner member 30 is dented from the upper end face of the heat dissipating part 21 could cause the center part of the heat dissipating part 21 to sink down while the lateral part warps upward, because of which the expected dimensions or shape may not be retained.

The heatsink A according to this embodiment can solve such issues as warping by using a pressing punch P having a smaller outer diameter than that of the inner member 30.

The heatsink A with the above configuration configures an electronic component package with an electronic component X brought into contact with the electronic component contact surface 11a as shown in FIG. 2.

This configuration can dissipate the heat transferred from the electronic component X and others efficiently to the heat dissipation space S between the base part 11 and the heat dissipating part 21 or to the space above the heat dissipating part 21, and moreover, allows the space inside the recess 32 to serve as a heat dissipation space.

### <Heatsink B>

Next, another heatsink according to the present invention is described. The heatsink depicted below is a result of some changes made to the above-described heatsink A and therefore these changes will mainly be discussed. The same reference numerals are given to the same parts as those of the heatsink A and repetitive description will be omitted.

The heatsink B shown in FIG. 4 and FIG. 5 is obtained by providing an inner cylindrical member 40 to the above-described heatsink A such as to be positioned between the inner peripheral surfaces of the insertion holes 10a and 20a and the outer peripheral surface of the inner member 30.

Namely, to produce this heatsink B, the base part 11, the column portions 12 and 22, and the heat dissipating part 21 are first stacked up on a flat surface plate in a similar way as described previously. The inner cylindrical member 40 is then inserted into these insertion holes 20a and 10a, and the inner member 30′ is inserted into this inner cylindrical member 40.

With the lower end faces of the base part 11, the inner cylindrical member 40, and the inner member 30 being flush on the above-mentioned flat surface (surface plate), the pressing punch P is pressed against the upper end face of the inner member 30′ to form the recess 32.

This brings the outer peripheral surface of the inner member 30 into pressure contact with the inner peripheral surface of the inner cylindrical member 40, causing the inner cylindrical member 40 to radially expand by plastic deformation, which in turn brings the outer peripheral surface of the inner cylindrical member 40 into pressure contact with the inner peripheral surfaces of the insertion holes 20a and 10a so that the base part 11, the column portion 12, the heat dissipating part 21, the column portion 22, the inner cylindrical member 40, and the inner member 30 are integrated.

The inner cylindrical member 40 is made of the same metal material as that of the inner member 30, for example, and formed in a cylindrical shape. The inner cylindrical member 40 has an outer diameter that is substantially the same as the inner diameters of the insertion holes 10a and 20a and that allows the inner cylindrical member to be inserted into the insertion holes 10a and 20a.

The axial length of the inner cylindrical member 40 in the illustrated example is substantially equal to the entire axial length from the base part 11 to the heat dissipating part 21.

The inner member 30′ of this heatsink B has an outer diameter that is substantially the same as the inner diameter of the inner cylindrical member 40 and that allows the inner member to be inserted into the insertion holes 10a and 20a. In the illustrated example, the axial length of the inner member is set slightly longer than that of the inner cylindrical member 40.

Therefore, according to the heatsink B shown in FIG. 4 and the manufacturing method thereof, similarly to the heatsink A, the base part 11, the column portion 12, the heat dissipating part 21, and the column portion 22 can be joined together even more firmly by the inner member 30 and the inner cylindrical member 40, and thus a high-quality heatsink with little warping of various parts can be provided.

The heat transferred from the electronic component X and others can be dissipated efficiently to the heat dissipation space S between the base part 11 and the heat dissipating part 21 or to the space above the heat dissipating part 21, and moreover, the space inside the recess 32 can serve as a heat dissipation space.

In manufacturing this heatsink B, moreover, the possibility of warping occurring in the heat dissipating part 21 or the base part 11 during the pressing process in which the recess 32 is formed by the pressing punch P can be reduced. Namely, in an embodiment in which no inner cylindrical member 40 is provided such as the heatsink A, the heat dissipating part 21 or the base part 11 could undergo warping during the pressing process due to the plastic deformation of the inner member 30. The heatsink B that uses the inner cylindrical member 40 can reduce the instances of such warping.

The inner cylindrical member 40 inserted into the base part 11, the column portion 12, the heat dissipating part 21, and the column portion 22 such as to extend therethrough can retain these parts coaxially during the production of the heatsink B and thus also contributes to favorable work efficiency.

### <Heatsink C>

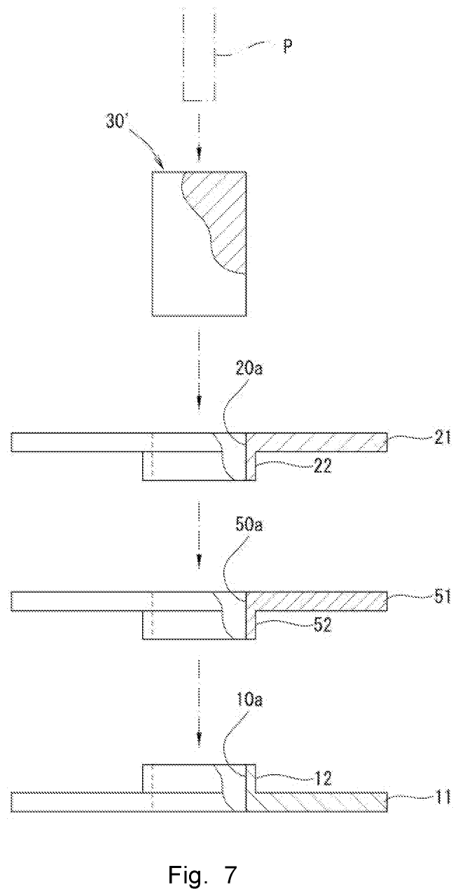

The heatsink C shown in FIG. 6 and FIG. 7 is equivalent of the above-described heatsink A provided with a tabular intermediate heat dissipating part 51 between the heat dissipating part 21 and the base part 11 such that the column portions 22, 52, and 12 and the heat dissipation spaces S are arranged on both sides in the thickness direction (in other words, axial direction).

The intermediate heat dissipating part 51 in the illustrated example has the same configuration as that of the heat dissipating part 21 or the base part 11.

A downwardly extending column portion 52 is integrated to a center portion of this intermediate heat dissipating part 51.

An insertion hole 50a with the same inner diameter as that of the insertion holes 10a and 20a extends through the intermediate heat dissipating part 51 and the column portion 52.

Namely, the three insertion holes 20a, 50a, and 10a are positioned coaxially and continuously and extend through the heat dissipating part 21, the intermediate heat dissipating part 51, the column portions 22, 52, and 12, and the base part 11.

The heat dissipating part 21, the intermediate heat dissipating part 51, the column portions 22, 52, and 12 on both sides, and the base part 11 are fixed together by the inner member 30 that is formed with a recess 32.

The manufacturing method of this heatsink C is described next. First, the base part 11 is placed on a flat surface plate with the column portion 12 upwards. The column portion 52 and the intermediate heat dissipating part 51 are stacked on top of the column portion 12, and further, the column portion 22 and the heat dissipating part 21 are stacked on top of the intermediate heat dissipating part 51 (see FIG. 7).

The inner member 30 is then inserted into the insertion holes 20a, 50a, and 10a of the heat dissipating part 21, the intermediate heat dissipating part 51, the base part 11, and the column portions 22, 52, and 12, and the pressing punch P is pressed against an upper end portion of the inner member 30 to form the recess 32 in the shape of the lower end of the pressing punch P.

During the pressing process, the inner member 30 plastically deforms radially outward so that its outer peripheral surface makes pressure contact with the inner peripheral surfaces of the insertion holes 20a, 50a and 10a.

Thus the heat dissipating part 21, the intermediate heat dissipating part 51, the base part 11, and the column portions 22, 52, and 12 are integrated by the inner member 30.

Therefore, according to the heatsink C shown in FIG. 6, similarly to the heatsink A, the heat dissipating part 21, the intermediate heat dissipating part 51, the base part 11, and the column portions 22, 52, and 12 can be joined firmly together by the inner member 30, and thus a high-quality heatsink with little warping of various parts can be provided.

The heat transferred from the electronic component and others can be dissipated efficiently to the heat dissipation spaces S on both sides of the intermediate heat dissipating part 51 and to the space above the heat dissipating part 21, and moreover, the space inside the recess 32 can serve as a heat dissipation space.

While one each intermediate heat dissipating part 51 and the column portion 52 are provided in the illustrated example, two or more intermediate heat dissipating parts 51 and column portions 52 (more than those of the illustrated example) may be stacked up. In this case, the inner member 30 may be made longer in accordance with the total axial dimension of the heat dissipating part 21 and the base part 11.

### <Heatsink D>

The heatsink D shown in FIG. 8 is obtained by removing the column portion 52 from the heatsink C so that the upper end of the column portion 12 directly abuts on the lower face of the column portion 52.

Namely, the intermediate heat dissipating part 51′ of this heatsink D is formed flat without a column portion and has an insertion hole 50a′ in a center portion thereof.

The insertion hole 20a of the heat dissipating part 21 and the column portion 22, the insertion hole 50a′ of the intermediate heat dissipating part 51′, and the insertion hole 10a of the base part 11 and the column portion 12 are coaxial and continuous.

The inner member 30 is inserted into these insertion holes 20a, 50a′ and 10a similarly to the above-described embodiments, and the recess 32 is formed in the upper end face of this inner member 30 by the pressing punch P.

Thus the heat dissipating part 21, the intermediate heat dissipating part 51′, the base part 11, and the column portions 22 and 12 are integrated by the radially expanded inner member 30.

Therefore, according to the heatsink D shown in FIG. 8, similarly to the above-described embodiments, various constituent elements can be joined firmly together by the inner member 30 that is formed with the recess 32, and thus a high-quality heatsink with little warping of various parts can be provided.

The heat transferred from the electronic component and others can be dissipated efficiently to the heat dissipation spaces S on both sides of the intermediate heat dissipating part 51′ and to the space above the heat dissipating part 21. Furthermore, the space inside the recess 32 can serve as a heat dissipation space.

### <Heatsink E>

The heatsink E shown in FIG. 10 is obtained by replacing the heat dissipating part 21 and the intermediate heat dissipating part 51′ of the heatsink E respectively with a heat dissipating part 21′ without the column portion 22, and an intermediate heat dissipating part 51 with an upward column portion 52.

The heat dissipating part 21′ is formed flat without the column portion and has an insertion hole 20a′ in a center portion thereof similarly to the above-described intermediate heat dissipating part 51′.

The insertion hole 20a′ of the heat dissipating part 21′, the insertion hole 50a of the intermediate heat dissipating part 51 and the column portion 52, and the insertion hole 10a of the base part 11 are coaxial and continuous.

The inner member 30 is inserted into these insertion holes 20a′, 50a, and 10a similarly to the above-described embodiments, and the recess 32 is formed in the upper end face of this inner member 30 by the pressing punch P.

Thus the heat dissipating part 21′, the intermediate heat dissipating part 51, the base part 11, and the column portions 52 and 12 are integrated by the inner member 30 that is radially expanded by plastic deformation.

The heatsink E with the above configuration can provide substantially similar effects as those of the above-described heatsink D.

### <Heatsink F>

The heatsink F shown in FIG. 11 is obtained by replacing the pressing punch P used in the manufacturing method of the heatsink A with a tapered pressing punch P′ to form a recess 32′ in the upper end face of the inner member 30.

In the part that forms the recess 32′, the pressing punch P′ has a smaller outer diameter at the distal end than the outer diameter therebehind. To be more specific, the above-mentioned part reduces gradually in diameter toward the distal end thereof, the tip being formed flat.

The manufacturing procedure of the heatsink F using the pressing punch P′ is similar to that of the heatsink A.

According to the manufacturing procedure of the heatsink F, the pressing punch P′ can be removed from the recess 32′ with reduced resistance, which in turn can improve the processing ease of the recess 32′. For example, the speed at which the pressing punch P′ is driven up and down can be increased to improve the productivity of the heatsink F.

According to the heatsink F with the above configuration, similarly to the above-described embodiments, various constituent elements can be joined firmly together by the inner member 30 that is formed with the recess 32′, and thus a high-quality heatsink with little warping of various parts can be provided.

The heat transferred from the electronic component X and others can be dissipated efficiently to the heat dissipation space S between the heat dissipating part 21 and the base part 11 or to the space above the heat dissipating part 21, and moreover, the space inside the recess 32′ can serve as a heat dissipation space.

In the above embodiment, the pressing punch P′ has an outer contour that gradually reduces in diameter toward the distal end as a particularly preferable example. In another example, this pressing punch may have a shape that reduces in diameter in multiple steps toward the distal end.

### <Heatsink G>

FIG. 12 illustrates a procedure of manufacturing a heatsink G, using a first pressing punch and a second pressing punch having a larger outer diameter than that of the first pressing punch.

This heatsink G is obtained by replacing the recess 32 of the heatsink A with a recess 33 to be described later.

The manufacturing method of this heatsink G is the same as that of the above-described heatsink A until the inner member 30′ is inserted into the insertion holes 20a and 10a of the heat dissipating part 21, the column portions 22 and 12, and the base part 11.

In the pressing process that follows, the first pressing punch P1 is first pressed against the upper end face of the inner member 30′ to form a small-diameter recess 33a (see FIGS. 12(a) and (b)). In the illustrated example, the first pressing punch P1 is similar to the one used in the manufacturing method of the above-described heatsink A, and has a relatively small diameter.

The small-diameter recess 33a formed in this first pressing process reaches to a depth that extends through the heat dissipating part 21 and the column portion 22, and into the column portion 12 in the illustrated example.

Next, the second pressing punch P2 is pressed against the upper end face of the inner member 30′ formed with the small-diameter recess 33a to form a large-diameter recess 33b that is shallower than the small-diameter recess 33a. This two-step pressing process forms a stepped recess 33 in the shape of a blind hole made up of the large-diameter recess 33b and the small-diameter recess 33a located in the center at the bottom of the large-diameter recess 33b, in the upper end face of the inner member 30.

The second pressing punch P2 has an outer contour larger than that of the first pressing punch P1 and smaller than that of the inner member 30′.

The depth of the large-diameter recess 33b in the illustrated example extends through the heat dissipating part 21 and into the column portion 22.

The upper end face of the inner member 30 slightly protrudes from the upper end face of the heat dissipating part 21 in the illustrated example.

According to the manufacturing method of the heatsink G, the stepwise pressing that uses the first and second pressing punches P1 and P2 enables axially uniform radial expansion of the inner member 30′, which in turn can increase the joint strength between the inner member 30 after the formation of the recess 33 and the heat dissipating part 21, the column portions 22 and 12, and the base part 11. Thus a heatsink with an even higher quality and little warping of various parts can be provided.

According to the heatsink G with the above configuration, similarly to the above-described embodiments, the heat transferred from the electronic component X and others can be dissipated efficiently to the heat dissipation space S between the heat dissipating part 21 and the base part 11 or to the space above the heat dissipating part 21.

Moreover, the recess 33 that is formed in the shape of a stepped hole has an inner face with a larger heat dissipation area, so that the space inside the recess 33 can serve as a heat dissipation space even more efficiently.

While the above embodiment uses two, first and second, pressing punches P1 and P2, in another example, these first and second pressing punches P1 and P2 may be replaced with a single stepped punch (not shown) having a shape that corresponds to the recess 33, and the stepped recess 33 may be formed in a one-step pressing process using this stepped punch.

In yet another example, three or more punches with different outer diameters may be used to form a recess that has more steps than the one in the illustrated example. In the case with this example, too, the three punches with different outer diameters may be replaced with a single stepped punch.

### <Heatsink G′>

The heatsink G′ shown in FIG. 13(d) has the same configuration as the above-described heatsink G, but the manufacturing process is different.

In the manufacturing process of this heatsink G′, the first pressing punch P1′ is pressed against the upper end face of the inner member 30′ that has been inserted into the heat dissipating part 21, the column portions 22 and 12, and the base part 11 to form a large-diameter recess 33b (see FIGS. 13(a) and (b)). The first pressing punch P1′ is similar to the second pressing punch P2 used for the heatsink G, and has a relatively large diameter.

The large-diameter recess 33b formed in this first pressing process reaches to a depth that extends through the heat dissipating part 21 and into the column portion 22.

Next, as shown in FIGS. 13(c) and (d), the second pressing punch P2′ is pressed against the upper end face of the inner member 30′ formed with the large-diameter recess 33b inside the area that has been pressed by the first pressing punch P1′ to form a small-diameter recess 33a that is deeper than the large-diameter recess 33b. This two-step pressing process forms a stepped recess 33 in the shape of a blind hole made up of the small-diameter recess 33a and the large-diameter recess 33b in the upper end face of the inner member 30.

The second pressing punch P2′ is similar to the first pressing punch P1 used for the heatsink G, and has a relatively small diameter.

The configuration of the heatsink G′ and the manufacturing method thereof can provide substantially similar effects as those of the above-described heatsink G.

### <Heatsink H>

In the manufacturing method shown in FIG. 14, the first pressing punch P1′ used in the manufacturing method of the heatsink G′ is replaced with a first pressing punch P1″ to form a recess 32 at the upper end of the inner member 30.

The first pressing punch P1″ has substantially the same outer diameter as that of the inner member 30′ and formed to be insertable into the insertion holes 20a and 10a.

In the manufacturing process of this heatsink H, the first pressing punch P1″ is pressed against the upper end face of the inner member 30′ that has been inserted into the heat dissipating part 21, the column portions 22 and 12, and the base part 11 to axially compress the inner member 30′, as well as to plastically deform it to increase in diameter. The upper end face of the inner member 30′ after this plastic deformation is positioned lower than the upper end face of the heat dissipating part 21 in the example shown in FIG. 14(b).

In other examples than the illustrated one, the length of the inner member 30′ in the above process may be changed so that the upper end portion of the inner member 30′ will be substantially flush with the upper end face of the heat dissipating part 21, or so that the upper end portion of the inner member 30′ will protrude upward beyond the upper end face of the heat dissipating part 21.

Next, the second pressing punch P2′ is pressed against the upper end face of the inner member 30′ to form a single recess 32.

In the example shown in FIG. 14(d), the upper end portion of the inner member 30 having the recess 32 is sunk down from the upper end face of the heat dissipating part 21. In another example in which the length of the inner member 30′ is changed as described above, the upper end portion of the inner member 30 may be substantially flush with the upper end face of the heat dissipating part 21, or the upper end portion of the inner member 30 may protrude upward beyond the upper end face of the heat dissipating part 21.

According to the manufacturing method of the heatsink H, the stepwise pressing that uses the first and second pressing punches P1″ and P2′ enables axially uniform radial expansion of the inner member 30′, which in turn can increase the joint strength between the inner member 30 after the formation of the recess 32 and the heat dissipating part 21, the column portions 22 and 12, and the base part 11.

The heatsink H with the above configuration can provide substantially similar effects as those of the above-described heatsink A.

### <Heatsink I>

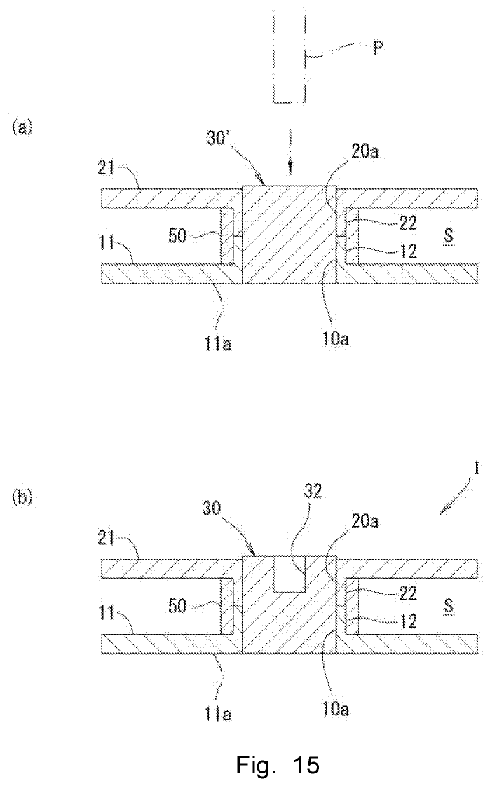

The heatsink I shown in FIG. 15 is obtained by a manufacturing method in which an outer cylindrical member 50 is provided to an outer circumferential part of the column portions 12 and 22 of the above-described heatsink A in an annular form, with the outer peripheral surfaces of the column portions 12 and 22 in pressure contact with an inner peripheral surface of the outer cylindrical member 50.

The outer cylindrical member 50 is made of the same metal material as that of the inner member 30, for example, and formed in a cylindrical shape. It fits on the outer circumference of the column portions 12 and 22, and is positioned between the base part 11 and the heat dissipating part 21.

The manufacturing method of this heatsink I is described in detail. First, the base part 11 is placed on a flat surface, with the column portion 12 upwards. The outer cylindrical member 50 is fitted on the column portion 12 in an annular form, and the heat dissipating part 21 is stacked thereon such that the column portion 22 is inserted into the outer cylindrical member 50. After that, the inner member 30′ is inserted into these internal insertion holes 20a and 10a (see FIG. 15(a)). The lower end of this inner member 30′ is abutted on the above-mentioned flat surface (such as a surface plate).

Next, the pressing punch P is pressed against a center portion at the upper end of the inner member 30′ to form a recess 32. During the pressing process, the inner member 30 plastically deforms radially outward so that its outer peripheral surface makes pressure contact with an inner peripheral surfaces of the column portions 12 and 22. The column portions 12 and 22 also plastically deform radially outward so that their outer peripheral surfaces make pressure contact with an inner peripheral surface of the outer cylindrical member 50.

Thus the base part 11, the column portion 12, the heat dissipating part 21, the column portion 22, and the outer cylindrical member 50 are integrally fixed together.

The heatsink I with the above configuration can provide substantially similar heat dissipation effects as those of the above-described heatsink A.

Moreover, the outer cylindrical member 50 can reduce the possibility of warping occurring in the base part 11 or the heat dissipating part 21 during the above-described pressing process. It can also join the base part 11 and the column portion 12 with the heat dissipating part 21 and the column portion 22 more firmly.

Thus a high-performance, high-quality, and high-strength heatsink can be provided.

The outer cylindrical member 50 can be applied to any of the heatsinks A to H described above.

Namely, in the case of applying it to the heatsink B (see FIG. 4), for example, the outer cylindrical member 50 may be used together with the inner cylindrical member 40.

In the case of applying it to the heatsinks C to E (see FIG. 6 to FIG. 10), the outer cylindrical members 50 may be attached to an outer circumferential part of the column portions 12, 22, and 52 in an annular form.

In the above embodiments, the recess is provided to the upper end face of the inner member. In other examples of embodiments, the recess may be formed in the lower end face of the inner member, or the recess may be formed in both of the upper end face and the lower end face of the inner member.

In the above embodiments, the recess is provided to the inner member as a particularly preferable example. In other examples than the illustrated ones in each of the embodiments, the recess may be omitted. Such alternative embodiments can also provide a firm joint between a plurality of components including the above-described base part, the heat dissipating part, the column portions, the intermediate heat dissipating part, etc., and can provide favorable heat dissipation performance.

The present invention is not limited to the embodiments described above and may be altered as required to the extent that it does not change the subject matter of the present invention.

### REFERENCE SIGNS LIST

11 Base part
11a Electronic component contact surface
21, 21′ Heat dissipating part
51, 51′ Intermediate heat dissipating part
12, 22, 52 Column portion
10a, 20a, 20a′, 50a, 50a′ Insertion hole
30, 30′ Inner member
32, 32′, 33 Recess
33a Small-diameter recess
33b Large-diameter recess
40 Inner cylindrical member
50 Outer cylindrical member
A to H, G′ Heatsink
P, P′ Pressing punch
P1, P1′, P1″ First pressing punch
P2, P2′ Second pressing punch

1. A heatsink comprising:
a tabular base part including an electronic component contact surface on a first side in a thickness direction thereof to make contact with an electronic component;
a tabular heat dissipating part arranged in parallel to the base part on a second side of the base part in the thickness direction across a heat dissipation space; and
a column portion provided between the base part and the heat dissipating part, wherein:
the heat dissipating part, the column portion, and the base part are provided with an insertion hole that extends therethrough; and
the heat dissipating part, the column portion, and the base part are fixed together by an inner member inserted into the insertion hole.

2. The heatsink according to claim 1, wherein the inner member has an outer peripheral surface in pressure contact with an inner peripheral surface of the insertion hole.

3. The heatsink according to claim 1, further comprising:
an inner cylindrical member inserted in the insertion hole, wherein
the inner member has an outer peripheral surface in pressure contact with an inner peripheral surface of the inner cylindrical member, and
the inner cylindrical member has an outer peripheral surface in pressure contact with an inner peripheral surface of the insertion hole.

4. The heatsink according to claim 1, further comprising
an outer cylindrical member provided in an annular form to an outer circumferential part of the column portion, wherein
the column portion has an outer peripheral surface in pressure contact with an inner peripheral surface of the outer cylindrical member.

5. The heatsink according to claim 1, further comprising
a tabular intermediate heat dissipating part provided between the heat dissipating part and the base part such that the column portion and a heat dissipation space are arranged on both sides in the thickness direction,
the insertion hole extends through the heat dissipating part, the intermediate heat dissipating part, the column portion, and the base part, and
the heat dissipating part, the intermediate heat dissipating part, the column portion, and the base part are fixed together by the inner member inserted into the insertion hole.

6. The heatsink according to claim 1, wherein the column portion is an integral part of the base part or the heat dissipating part.

7. The heatsink according to claim 1, wherein a recess is provided in an end face of the inner member on the first or second side.

8. The heatsink according to claim 7, wherein the recess extends at least through the heat dissipating part or the base part into the column portion.

9. The heatsink according to claim 7, wherein the recess has an inner diameter set in a range of 20% to 80% of an outer diameter of the inner member.

10. The heatsink according to claim 7, wherein the recess has a depth set in the range of 30% to 70% of a length of the inner member.

11. A manufacturing method of the heatsink according to claim 7, the method comprising:
inserting the inner member into the insertion hole; and
pressing by forming the recess in the end face of the inner member by pressing the end face with a pressing punch having an outer diameter smaller than that of the inner member.

12. The manufacturing method according to claim 11, wherein the pressing punch, in a portion that forms the recess, has a smaller outer diameter at a distal end than an outer diameter therebehind.

13. The manufacturing method according to claim 11, wherein the pressing punch has a portion that forms the recess, the portion gradually reducing in diameter toward a distal end thereof.

14. The manufacturing method according to claim 11, wherein
a first pressing punch and a second pressing punch having a larger outer diameter than that of the first pressing punch are used as the pressing punch, and
in the pressing, the first pressing punch is pressed against the end face of the inner member, after which the second pressing punch is pressed against the end face of the inner member, to form the recess.

15. The manufacturing method according to claim 11, wherein
a first pressing punch and a second pressing punch having a smaller outer diameter than that of the first pressing punch are used as the pressing punch, and
in the pressing, the first pressing punch is pressed against the end face of the inner member, after which the second pressing punch is pressed against the end face inside an area that has been pressed, to form the recess.

16. The manufacturing method according to claim 14, wherein the recess is formed in a shape of a stepped hole comprising a small-diameter recess and a large-diameter recess formed respectively by one and the other of the first pressing punch and the second pressing punch.

17. The manufacturing method according to claim 15, wherein the first pressing punch has an outer diameter that is substantially equal to that of the inner member.

18. An electronic component package using the heatsink according to claim 1 and comprising an electronic component in contact with the electronic component contact surface.

19. The manufacturing method according to claim 15, wherein the recess is formed in a shape of a stepped hole comprising a small-diameter recess and a large-diameter recess formed respectively by one and the other of the first pressing punch and the second pressing punch.
